(19) United States
(12) Patent Application Publication
(10) Pub. No.: US 2023/0136604 A1
(43) Pub. Date: May 4, 2023

(54) SEMICONDUCTOR DEVICE

(71) Applicant: SUMITOMO ELECTRIC INDUSTRIES, LTD., Osaka (JP)

(72) Inventor: Hiroshi NOTSU, Osaka (JP)

(21) Appl. No.: 17/912,509

(22) PCT Filed: Mar. 17, 2021
(86) PCT No.: PCT/JP2021/010735

§ 371 Date: Sep. 18, 2022

(30) Foreign Application Priority Data
Mar. 31, 2020 (JP) 2020-061725

(51) Int. Cl. H01L 29/16; H01L 29/417; H01L 29/45; H01L 21/477

(52) U.S. Cl. CPC H01L 29/1608; H01L 29/41716; H01L 29/458; H01L 21/477; H01L 2021/60015

(57) ABSTRACT

A semiconductor device includes a conductive substrate, a conductive first joint portion arranged on the substrate, a SiC diode chip arranged on the first joint portion, a conductive second joint portion arranged on the SiC diode chip, and a transistor chip arranged on the second joint portion. The SiC diode chip includes a cathode pad arranged on one end and an anode pad arranged on the other end in the thickness direction. The cathode pad is joined to the substrate by the first joint portion. The transistor chip includes a drain electrode arranged on one end in the thickness direction. The anode pad is joined with the drain electrode by the second joint portion. The anode pad is arranged in a region enclosed by an outer edge of the SiC diode chip as viewed in a thickness direction of the substrate. The anode pad has an area larger than that of the transistor chip as viewed in the thickness direction of the substrate.

### TECHNICAL FIELD

The present disclosure relates to a semiconductor device.

The present application claims priority based on Japanese Patent Application No. 2020-061725 filed on Mar. 31, 2020, the entire contents of which are incorporated herein by reference.

### BACKGROUND ART

A power module semiconductor device having a plurality of semiconductor chips arranged on a substrate is disclosed (see, e.g., Patent Literature 1).

### CITATION LIST

### Patent Literature

Patent Literature 1: Japanese Patent Application Laid-Open No. 2019-117944

### SUMMARY OF INVENTION

A semiconductor device according to the present disclosure includes: a substrate having conductivity; a first joint portion having conductivity, arranged on the substrate; a SiC diode chip arranged on the first joint portion; a second joint portion having conductivity, arranged on the SiC diode chip; and a transistor chip arranged on the second joint portion. The SiC diode chip includes a cathode pad arranged on one end in a thickness direction and an anode pad arranged on another end in the thickness direction. The cathode pad is joined to the substrate by the first joint portion. The transistor chip includes a drain electrode arranged on one end in a thickness direction. The drain electrode is joined to the anode pad by the second joint portion. As viewed in a thickness direction of the substrate, the anode pad is arranged in a region enclosed by an outer edge of the SiC diode chip. As viewed in the thickness direction of the substrate, the anode pad has an area larger than an area of the transistor chip.

### BRIEF DESCRIPTION OF DRAWINGS

FIG. 1 is a schematic plan view showing the appearance of a semiconductor device in Embodiment 1;

FIG. 2 is a diagram showing a portion of the semiconductor device shown in FIG. 1;

FIG. 3 is a schematic cross-sectional view of a portion of the semiconductor device shown in FIG. 1;

FIG. 4 is an enlarged schematic cross-sectional view of a portion of the semiconductor device shown in FIG. 3;

FIG. 5 is a schematic cross-sectional view showing a SiC transistor chip placed on a SiC diode chip;

FIG. 6 is a schematic plan view showing a state in which a copper plate is processed in an exemplary method of producing the semiconductor device shown in FIG. 1;

FIG. 7 is a schematic plan view showing a state in which a SiC diode chip is joined on the processed copper plate in the exemplary method of producing the semiconductor device shown in FIG. 1;

FIG. 8 is a schematic plan view showing a state in which a SiC transistor chip is joined on the SiC diode chip in the exemplary method of producing the semiconductor device shown in FIG. 1;

FIG. 9 is a schematic plan view showing a state in which members are joined by wires in the exemplary method of producing the semiconductor device shown in FIG. 1;

FIG. 10 is a schematic plan view showing a state of being encapsulated with an encapsulating material in the exemplary method of producing the semiconductor device shown in FIG. 1;

FIG. 11 is a schematic cross-sectional view of a portion of a semiconductor devices in Embodiment 2;

FIG. 12 is a schematic cross-sectional view of a portion of a semiconductor devices in Embodiment 3;

FIG. 13 is an enlarged schematic cross-sectional view of a portion of the semiconductor device shown in FIG. 12;

FIG. 14 is a schematic cross-sectional view of a portion of a semiconductor device in Embodiment 4;

FIG. 15 is a schematic cross-sectional view of a portion of a semiconductor device in Embodiment 5;

FIG. 16 is a schematic cross-sectional view of a portion of a semiconductor device in Embodiment 6; and

FIG. 17 is a diagram illustrating an equivalent circuit in Embodiment 7.

### DESCRIPTION OF EMBODIMENTS

### Problems to be Solved by Present Disclosure

According to Patent Literature 1, in the power module semiconductor device, semiconductor chips having a semiconductor layer made of SiC and capable of carrying a large current are adopted. In Patent Literature 1, a diode chip and a transistor chip are arranged in separate regions on the substrate, and the diode chip and the transistor chip are connected by a wire. However, in such a configuration, a region for arranging the diode chip and a region for arranging the transistor chip have to be secured separately on the substrate as viewed in the thickness direction of the substrate. This leads to a large area occupied by each chip, making it difficult to achieve downsizing of the semiconductor device. It is also required to secure the heat dissipation of the transistor chip, which generates heat when a large current is applied.

Therefore, one of the objects is to provide a semiconductor device that can be downsized while ensuring the heat dissipation of the transistor chip.

### Advantageous Effects of Present Disclosure

According to the above semiconductor device, it is possible to achieve downsizing while ensuring the heat dissipation of the transistor chip.

### Description of Embodiments of Present Disclosure

First, embodiments of the present disclosure will be listed and described. A semiconductor device according to the present disclosure includes: a substrate having conductivity; a first joint portion having conductivity, arranged on the substrate; a SiC diode chip arranged on the first joint portion; a second joint portion having conductivity, arranged on the SiC diode chip; and a transistor chip arranged on the second joint portion. The SiC diode chip includes a cathode pad arranged on one end in a thickness direction and an anode pad arranged on another end in the thickness direction. The cathode pad is joined to the substrate by the first joint portion. The transistor chip includes a drain electrode arranged on one end in a thickness direction. The drain electrode is joined to the anode pad by the second joint portion. As viewed in a thickness direction of the substrate, the anode pad is arranged in a region enclosed by an outer edge of the SiC diode chip. As viewed in the thickness direction of the substrate, the anode pad has an area larger than an area of the transistor chip.

The semiconductor device of the present disclosure includes the SiC diode chip. The above semiconductor device adopts a configuration in which the transistor chip is stacked on the SiC diode chip and the chips are electrically connected in series. Thus, by making the region in which the transistor chip is arranged overlaid on the region in which the SiC diode chip is arranged as viewed in the thickness direction of the substrate, the area occupied by the chips can be made smaller than in the case where the chips are arranged side by side.

The SiC diode chip has low on-resistance and high breakdown voltage, and can be used even at high temperatures. During operation, since the SiC diode chip and the transistor chip are electrically connected in series, a large amount of heat is generated by the transistor chip when a large current is applied. Here, the SiC diode chip has high thermal conductivity. Further, the area of the anode pad is larger than that of the transistor chip. Therefore, the heat generated in the transistor chip during operation can be efficiently transferred to the SiC diode chip side and dissipated to the substrate side.

Accordingly, the above semiconductor device can be easily downsized while ensuring the heat dissipation of the transistor chip.

In the above semiconductor device, as viewed in the thickness direction of the substrate, a shortest distance from the outer edge of the SiC diode chip to an outer edge of the transistor chip may be larger than a thickness of the SiC diode chip. The heat generated in the transistor chip is transferred to the substrate side via the SiC diode chip. Here, the rate of thermal diffusion in the thickness direction of the SiC diode chip and the rate of thermal diffusion in the direction perpendicular to the thickness direction are about the same. Therefore, much of the heat generated in the transistor chip is transferred into the SiC diode chip, with the range making an angle of 45 degrees relative to the thickness direction as a heat dissipation path. Adopting the above configuration can suppress the narrowing of the heat dissipation path in the SiC diode chip from the transistor chip to the substrate, allowing the heat generated in the transistor chip to be efficiently transferred to the substrate via the SiC diode chip. Efficient heat dissipation is thus possible.

In the above semiconductor device, the transistor chip may be a SiC transistor chip. The SiC transistor chip has low on-resistance and high breakdown voltage, and can be used even at high temperatures. It also has high thermal conductivity. Therefore, the heat dissipation of the transistor chip can be secured more reliably.

In the above semiconductor devices, a SiC crystal constituting the SiC diode chip may have a 4H structure. A SiC crystal constituting the SiC transistor chip may have a 4H structure. The SiC crystal constituting the SiC diode chip and the SiC crystal constituting the SiC transistor chip may have (0001) planes parallel to each other. SiC has different physical properties depending on the plane orientation, and behaves differently in terms of thermal expansion and warping during heat generation. The above configuration enables aligning the plane orientations of the SiC diode chip and the SiC transistor chip, and can suppress the generation of thermal stress during operation. Long-term reliability can thus be improved.

In the above semiconductor device, the SiC crystal constituting the SiC diode chip and the SiC crystal constituting the SiC transistor chip may have (11-20) planes parallel to each other. This also enables aligning the plane orientations of the SiC diode chip and the SiC transistor chip, thereby suppressing the generation of thermal stress during operation. Thus, long-term reliability can be improved.

In the above semiconductor device, the second joint portion may contain a sintered bonding material that is a sintered material of fine metal particles. Such a sintered bonding material has high thermal conductivity, enabling more efficient heat dissipation.

In the above semiconductor device, the second joint portion may include a first metal plate that is 30% or more of a thickness of the SiC diode chip. The first metal plate may have a region that does not overlap with the transistor chip as viewed in the thickness direction of the substrate. This makes it possible to secure electrical connection by using the region of the first metal plate that does not overlap with the transistor chip. Further, the first metal plate has high thermal conductivity. Therefore, the heat dissipation of the transistor chip can be secured by the first metal plate as well.

The above semiconductor device may further include a solder resist portion arranged on the anode pad and dividing a region on the anode pad. The second joint portion may include a solder portion. The solder resist portion may divide the region on the anode pad into a first region in which the solder portion and the transistor chip are arranged and a second region outside the first region as viewed in the thickness direction of the substrate. With this, when the solder portion included in the second joint portion is melted at the time of joining, the solder resist portion can suppress the solder portion from getting wet and spreading to the second region side.

The above semiconductor device may further include a second metal plate joined to a region outside a region in which the transistor chip is arranged. The second metal plate can easily carry a large current as compared to, for example, a wire. With the above configuration, the second metal plate joined to the region outside the region in which the transistor chip is arranged can be effectively used for electrical connection.

### Details of Embodiments of Present Disclosure

Embodiments of the semiconductor device of the present disclosure will be described below with reference to the drawings. In the drawings referenced below, the same or corresponding portions are denoted by the same reference numerals and the description thereof will not be repeated.

### Embodiment 1

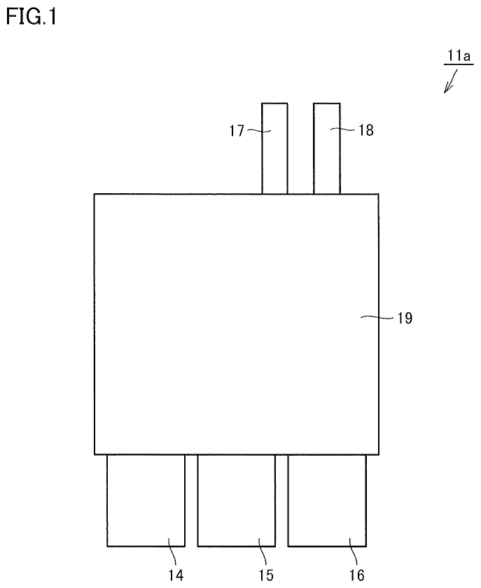

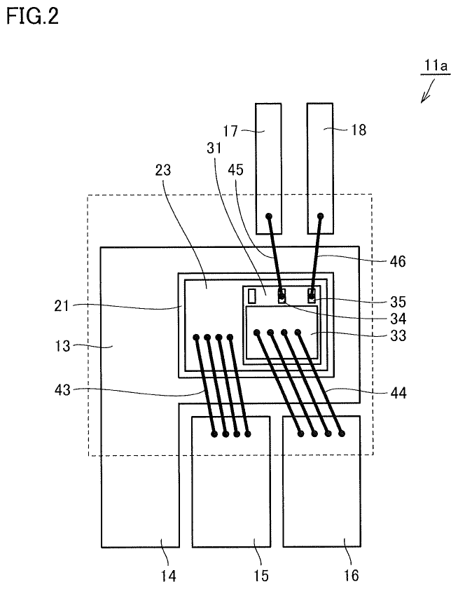

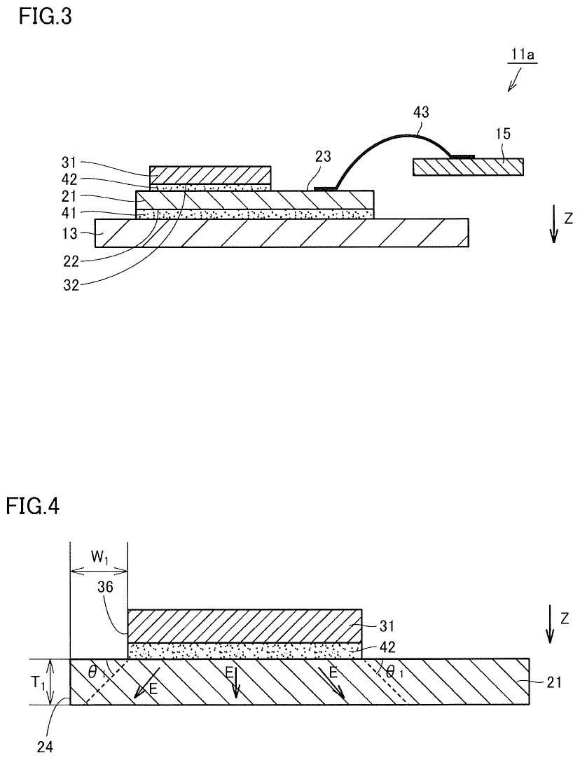

A semiconductor device according to Embodiment 1 of the present disclosure will be described. FIG. 1 is a schematic plan view showing an appearance of the semiconductor device in Embodiment 1. FIG. 2 is a diagram showing a portion of the semiconductor device shown in FIG. 1. In FIG. 2, illustration of an encapsulating material in the semiconductor device shown in FIG. 1 is omitted. FIG. 3 is a schematic cross-sectional view of a portion of the semiconductor device shown in FIG. 1. In FIG. 3, an arrow Z indicates a thickness direction of a substrate.

Referring to FIGS. 1, 2, and 3, a semiconductor device 11a according to Embodiment 1 includes a substrate 13 having conductivity, a first electrode terminal 14 formed integrally with the substrate 13, a second electrode terminal 15 arranged spaced apart from the substrate 13, a third electrode terminal 16 arranged spaced apart from the substrate 13 and the second electrode terminal 15, a gate terminal 17 arranged spaced apart from the substrate 13, and a Kelvin source terminal 18 arranged spaced apart from the substrate 13. The substrate 13, the first electrode terminal 14, the second electrode terminal 15, the third electrode terminal 16, the gate terminal 17, and the Kelvin source terminal 18 are specifically made of copper, for example. In FIG. 2, the location of an encapsulating material 19, described below, for encapsulation of the substrate 13 is indicated by a broken line.

The semiconductor device 11a includes an encapsulating material 19 made of, for example, epoxy resin. The encapsulating material 19 covers a region on the substrate 13 and encapsulates an electronic circuit including a SiC diode chip 21 and a SiC transistor chip 31, which will be described later. The first electrode terminal 14, the second electrode terminal 15, the third electrode terminal 16, the gate terminal 17, and the Kelvin source terminal 18 are each partially exposed from the encapsulating material 19, ensuring electrical connection with the outside of the semiconductor device 11a.

The semiconductor device 11a includes a first joint portion 41 having conductivity. The first joint portion 41 contains a sintered bonding material that is a sintered material of fine metal particulates. The fine metal particulates are specifically fine particles of silver, copper, or nickel, for example. The first joint portion 41 is arranged on the substrate 13.

The semiconductor device 11a includes a SiC diode chip 21 including a cathode pad 22 and an anode pad 23. The SiC diode chip 21 is a semiconductor chip including a semiconductor layer made of SiC. The cathode pad 22 is arranged on one end in the thickness direction of the SiC diode chip 21. The anode pad 23 is arranged on the other end in the thickness direction of the SiC diode chip 21. As viewed in the thickness direction of the substrate 13, the anode pad 23 is arranged in a region enclosed by an outer edge of the SiC diode chip 21. In the present embodiment, as viewed in the thickness direction of the substrate 13, the anode pad 23 is provided at a distance from the outer edge of the SiC diode chip 21, as shown in FIG. 2. In the SiC diode chip 21, a current flows in the thickness direction of the substrate 13. The external shape of the SiC diode chip 21 is a rectangular shape as viewed in the thickness direction. A SiC crystal that constitutes the SiC diode chip 21 has a 4H structure.

The first joint portion 41 electrically joins the substrate 13 and the SiC diode chip 21. Specifically, the substrate 13 and the cathode pad 22 included in the SiC diode chip 21 are joined by the first joint portion 41. That is, the cathode pad 22 is joined to the substrate 13 by the first joint portion 41.

The semiconductor device 11a includes a second joint portion 42 having conductivity. The second joint portion 42 contains a sintered bonding material that is a sintered material of fine metal particulates. The fine metal particles are specifically fine particles of silver, copper, or nickel, for example. The second joint portion 42 is arranged on the SiC diode chip 21. Specifically, the second joint portion 42 is arranged on the anode pad 23 of the SiC diode chip 21.

The semiconductor device 11a includes a SiC transistor chip 31, which is a transistor chip including a drain electrode 32, a source pad 33, a gate pad 34, and a Kelvin source pad 35. The SiC transistor chip 31 is a semiconductor chip including a semiconductor layer made of SiC. The drain electrode 32 is arranged on one end in the thickness direction of the SiC transistor chip 31. The source pad 33, the gate pad 34, and the Kelvin source pad 35 are arranged on the other end in the thickness direction of the SiC transistor chip 31. The source pad 33, the gate pad 34, and the Kelvin source pad 35 are arranged spaced apart from each other. The SiC transistor chip 31 is a vertical transistor chip. In the SiC transistor chip 31, a current flows in the thickness direction of the substrate 13. The external shape of the SiC transistor chip 31 as viewed in the thickness direction is a rectangular shape. A SiC crystal that constitutes the SiC transistor chip 31 has a 4H structure. It should be noted that the Kelvin source pad 35 and the Kelvin source terminal 18 are not necessarily essential and can be omitted. That is, the semiconductor device 11a may not include the Kelvin source pad 35 and the Kelvin source terminal 18.

The second joint portion 42 electrically joins the SiC diode chip 21 and the SiC transistor chip 31. Specifically, the anode pad 23 included in the SiC diode chip 21 and the drain electrode 32 included in the SiC transistor chip 31 are joined by the second joint portion 42. That is, the drain electrode 32 is joined to the anode pad 23 by the second joint portion 42. The SiC diode chip 21 and the SiC transistor chip 31 are electrically connected in series.

Here, regarding the arrangement of the SiC transistor chip 31 relative to the SiC diode chip 21, a shortest distance from the outer edge of the SiC diode chip 21 to the outer edge of the SiC transistor chip 31, as viewed in the thickness direction of the substrate 13, is larger than a thickness of the SiC diode chip 21. This will be described later.

The SiC crystal that constitutes the SiC diode chip 21 and the SiC crystal that constitutes the SiC transistor chip 31 have their (0001) planes parallel to each other. That is, the SiC diode chip 21 and the SiC transistor chip 31 are joined such that the (0001) plane of the SiC crystal constituting the SiC diode chip 21 and the (0001) plane of the SiC crystal constituting the SiC transistor chip 31 are parallel to each other. Further, the SiC crystal that constitutes the SiC diode chip 21 and the SiC crystal that constitutes the SiC transistor chip 31 have their (11-20) planes parallel to each other. That is, the SiC diode chip 21 and the SiC transistor chip 31 are joined such that the (11-20) plane of the SiC crystal constituting the SiC diode chip 21 and the (11-20) plane of the SiC crystal constituting the SiC transistor chip 31 are parallel to each other.

The semiconductor device 11a includes a plurality of wires 43, 44, 45, and 46. The second electrode terminal 15 and the anode pad 23 of the SiC diode chip 21 are electrically joined by a plurality of wires 43. The third electrode terminal 16 and the source pad 33 of the SiC transistor chip 31 are electrically joined by a plurality of wires 44. The gate terminal 17 and the gate pad 34 of the SiC transistor chip 31 are electrically joined by the wire 45. The Kelvin source terminal 18 and the Kelvin source pad 35 of the SiC transistor chip 31 are electrically joined by the wire 46.

Here, as viewed in the thickness direction of the substrate 13, the anode pad 23 has an area larger than that of the SiC transistor chip 31. Specifically, the area of the SiC transistor chip 31 is slightly larger than half the area of the anode pad 23.

The above semiconductor device 11a includes the SiC diode chip 21. The above semiconductor device 11a adopts a configuration in which the SiC transistor chip 31 is stacked on the SiC diode chip 21 and the chips are electrically connected in series. Thus, by making the region in which the SiC transistor chip 31 is arranged overlaid on the region in which the SiC diode chip 21 is arranged as viewed in the thickness direction of the substrate 13, the area occupied by the chips can be made smaller than in the case where the chips are placed side by side.

The SiC diode chip 21 has low on-resistance and high breakdown voltage, and can be used even at high temperatures. During operation, since the SiC diode chip 21 and the SiC transistor chip 31 are electrically connected in series, a large amount of heat is generated by the SiC transistor chip 31 when a large current is applied. Here, the SiC diode chip 21 has high thermal conductivity. Further, the area of the anode pad 23 is larger than that of the SiC transistor chip 31. Therefore, the heat generated in the SiC transistor chip 31 during operation can be efficiently transferred to the SiC diode chip 21 side and dissipated to the substrate 13 side.

Accordingly, the above semiconductor device 11a can be easily downsized while ensuring the heat dissipation of the SiC transistor chip 31.

The SiC transistor chip 31 is joined to the SiC diode chip 21 by the second joint portion 42. According to this configuration, the current path between the SiC diode chip 21 and the SiC transistor chip 31 is shortened, leading to reduced inductance.

In the present embodiment, the shortest distance from the outer edge of the SiC diode chip 21 to the outer edge of the SiC transistor chip 31 as viewed in the thickness direction of the substrate 13 is larger than the thickness of the SiC diode chip 21. This enables efficient heat dissipation of the SiC transistor chip 31.

FIG. 4 is an enlarged schematic cross-sectional view of a portion of the semiconductor device 11a shown in FIG. 3. Referring to FIG. 4, the heat generated in the SiC transistor chip 31 is transferred to the substrate 13 side via the second joint portion 42, the SiC diode chip 21, and the first joint portion 41. Here, consideration is given to the heat transferred from the transistor chip 31 to the SiC diode chip 21. The rate of thermal diffusion in the thickness direction of the SiC diode chip 21 and the rate of thermal diffusion in the direction perpendicular to the thickness direction are the same. Therefore, much of the heat generated in the SiC transistor chip 31 is transferred to the SiC diode chip 21, with the range that makes an angle of 45 degrees, shown by angle θ₁ in FIG. 4, from an outer edge 36 of the SiC transistor chip 31 relative to the thickness direction as a heat dissipation path. In FIG. 4, an arrow E indicates a part of the heat dissipation path.

Here, a shortest distance W₁ from an outer edge 24 of the SiC diode chip 21 to the outer edge 36 of the SiC transistor chip 31 is larger than a thickness T₁ of the SiC diode chip 21. With this, the heat dissipation path in the SiC diode chip 21 from the SiC transistor chip 31 to the substrate 13 can be suppressed from becoming narrower, and the heat generated in the SiC transistor chip 31 can be efficiently transferred to the substrate 13 via the SiC diode chip 21. Therefore, the above semiconductor device 11a is a semiconductor device capable of efficient heat dissipation.

In the case where the SiC transistor chip 31 has a rounded quadrangular shape in cross section when viewed along a plane perpendicular to the thickness direction of the substrate 13, the outer edge of the chip is as follows. FIG. 5 is a schematic cross-sectional view of the SiC transistor chip 31 placed on the SiC diode chip 21. Referring to FIG. 5, when the SiC transistor chip 31 has a rounded corner 71 as viewed along a plane perpendicular to the thickness direction of the substrate 13, the position of an intersection 74 at which extensions of a first side 72 and a second side 73 constituting the corner 71 intersect with each other is regarded as the position of the outer edge 36 of the SiC transistor chip 31. The same applies to the outer edge 24 of the SiC diode chip 21.

In the present embodiment, the transistor chip is the SiC transistor chip 31. The SiC transistor chip 31 has low on-resistance and high breakdown voltage, and can be used even at high temperatures. It also has high thermal conductivity. Therefore, the above semiconductor device 11a is a semiconductor device that further ensures the heat dissipation of the transistor chip.

In the present embodiment, a SiC crystal that constitutes the SiC diode chip 21 has a 4H structure. A SiC crystal that constitutes the SiC transistor chip 31 has a 4H structure. The SiC crystal constituting the SiC diode chip 21 and the SiC crystal constituting the SiC transistor chip 31 have their (0001) planes parallel to each other. This enables aligning the plane orientations of the SiC diode chip 21 and the SiC transistor chip 31 and can suppress the generation of thermal stress during operation. Therefore, the above semiconductor device 11a is a semiconductor device that can be improved in long-term reliability.

In the present embodiment, the SiC crystal constituting the SiC diode chip 21 and the SiC crystal constituting the SiC transistor chip 31 have their (11-20) planes parallel to each other. With this, the plane orientations of the SiC diode chip 21 and the SiC transistor chip 31 can be aligned to suppress the generation of thermal stress during operation. Therefore, the above semiconductor device 11a is a semiconductor device that can be improved in long-term reliability.

In the present embodiment, the second joint portion 42 contains a sintered bonding material that is a sintered material of fine metal particles. Such a sintered bonding material has high thermal conductivity. Therefore, the above semiconductor device 11a is a semiconductor device capable of more efficient heat dissipation. In the present embodiment, the first joint portion 41 also contains the sintered bonding material as a sintered material of fine metal particles. Therefore, the above semiconductor device 11a is a semiconductor device capable of still more efficient heat dissipation.

Here, an exemplary method of producing the semiconductor device 11a in Embodiment 1 will be briefly described. First, a copper plate that is flat and rectangular in external shape as viewed in the thickness direction is prepared. The thickness of this copper plate is, for example, 1 mm. A predetermined portion of the prepared copper plate is punched out to form external shapes of the substrate, the first electrode terminal, the second electrode terminal, and the third electrode terminal included in the semiconductor device.

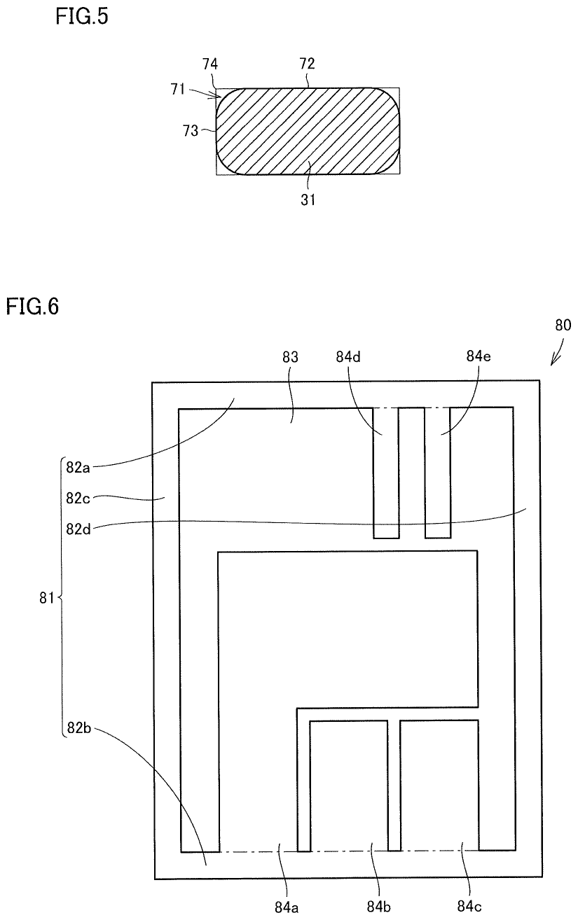

FIG. 6 is a schematic plan view showing the state in which a copper plate is processed in the exemplary method of producing the semiconductor device 11a shown in FIG. 1. Referring to FIG. 6, a copper plate 80 has a portion corresponding to a space 83 punched out in the thickness direction. The copper plate 80 includes a lead frame 81 made up of a first portion 82a, a second portion 82b, a third portion 82c, and a fourth portion 82d. The first portion 82a and the second portion 82b are arranged at positions corresponding to a pair of short sides of the rectangle. The third portion 82c and the fourth portion 82d are arranged at positions corresponding to a pair of long sides of the rectangle. The first portion 82a and the second portion 82b are arranged to oppose each other, and the third portion 82c and the fourth portion 82d are arranged to oppose each other. Connected to the second portion 82b are: a region 84a that is to be the first electrode terminal 14 and the substrate 13, a region 84b that is to be the second electrode terminal 15, and a region 84c that is to be the third electrode terminal 16. Connected to the first portion 82a are: a region 84d that is to be the gate terminal 17, and a region 84e that is to be the Kelvin source terminal 18. It should be noted that the boundaries between the lead frame 81 and the regions 84a to 84e are indicated with the chain-dotted lines.

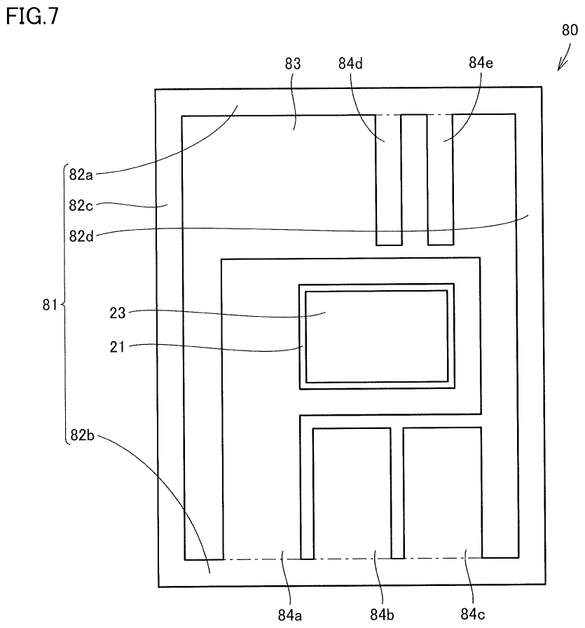

Next, a SiC diode chip 21 is joined on the region corresponding to the substrate 13. FIG. 7 is a schematic plan view showing the state in which the SiC diode chip 21 is joined on the processed copper plate in the exemplary method of producing the semiconductor device 11a shown in FIG. 1. Referring to FIG. 7, the SiC diode chip 21 is joined on the region corresponding to the substrate 13 by the first joint portion 41.

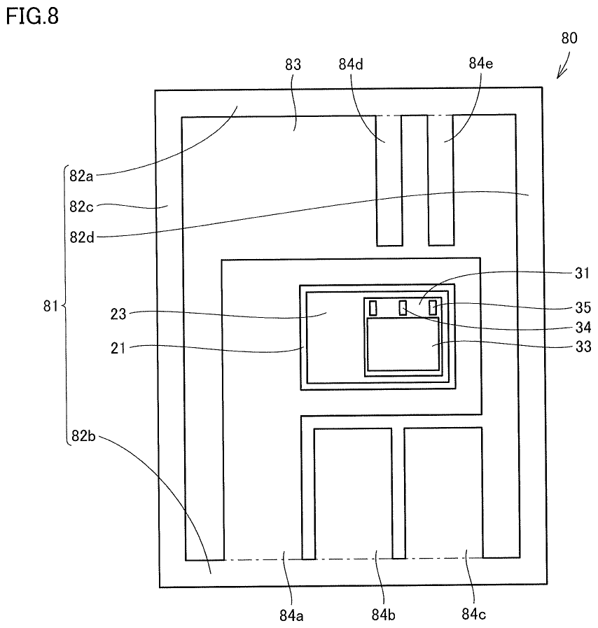

Next, a SiC transistor chip 31 is joined on the SiC diode chip 21. FIG. 8 is a schematic plan view showing the state in which the SiC transistor chip 31 is joined on the SiC diode chip 21 in the exemplary method of producing the semiconductor device 11a shown in FIG. 1. Referring to FIG. 8, the SiC transistor chip 31 is joined on the anode pad 23 of the SiC transistor chip 31 by the second joint portion 42.

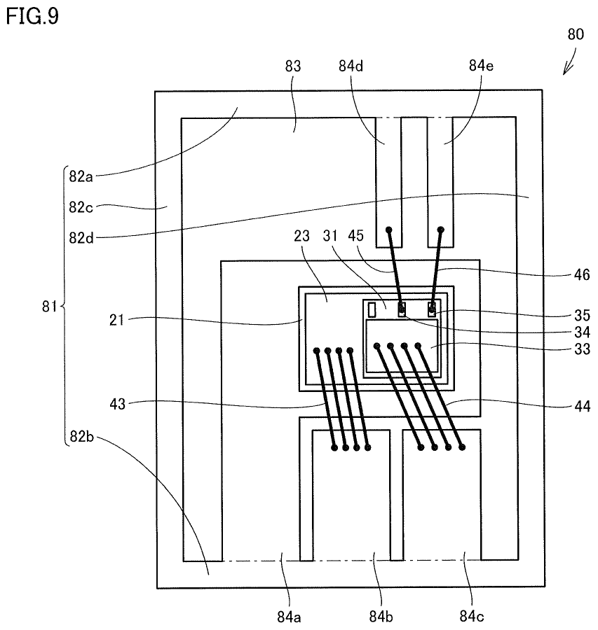

Next, wires are used to join the members. FIG. 9 is a schematic plan view showing the state in which the members are joined by means of wires in the exemplary method of producing the semiconductor device 11a shown in FIG. 1. Referring to FIG. 9, the region 84b and the anode pad 23 of the SiC diode chip 21 are connected by the wires 43. The region 84c and the source pad 33 of the SiC transistor chip 31 are connected by the wires 44. The region 84d and the gate pad 34 of the SiC transistor chip 31 are connected by the wire 45. The region 84e and the Kelvin source pad of the SiC transistor chip 31 are connected by the wire 46. In this case, for example, the wires 43 to 46 are connected by wire bonding using, e.g., ultrasonic bonding.

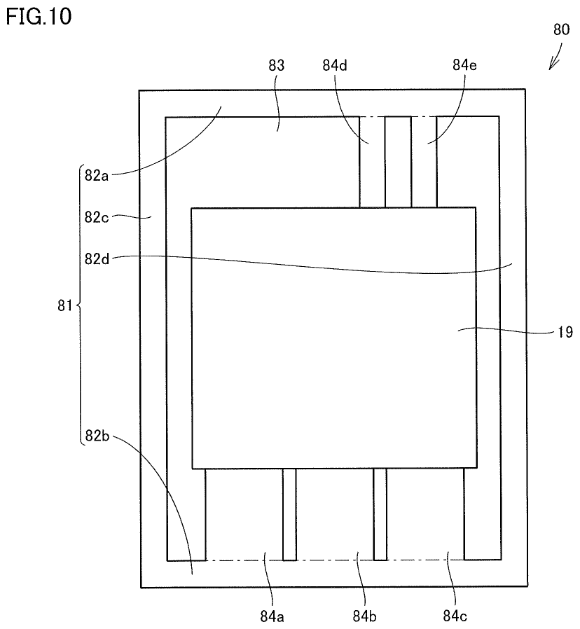

Next, a predetermined portion is encapsulated with an encapsulating material. FIG. 10 is a schematic plan view showing the state of being encapsulated with an encapsulating material 19 in the exemplary method of producing the semiconductor device 11a shown in FIG. 1. Referring to FIG. 10, the copper plate 80 is encapsulated with the encapsulating material 19 so as to partially expose the regions 84a to 84e and to cover the substrate 13 and the portions connected by the wires 43 to 46.

The copper plate 80 is then cut at the boundaries indicated with the chain-dotted lines, thereby separating the lead frame 81. The semiconductor device 11a in Embodiment 1 is thus obtained. The semiconductor device 11a in Embodiment 1 is produced, for example, as described above.

### Embodiment 2

A description will now be made of another embodiment, Embodiment 2. FIG. 11 is a schematic cross-sectional view of a portion of the semiconductor device in Embodiment 2. The semiconductor device of Embodiment 2 differs from that of Embodiment 1 in that the device includes a solder resist portion placed on the anode pad and that the second joint portion includes a solder portion.

Referring to FIG. 11, a semiconductor device 11b according to Embodiment 2 includes a solder resist portion 47 arranged on the anode pad 23. The solder resist portion 47 is made of a resin such as polyimide. The solder resist portion 47 is formed, for example, by film patterning in the process of producing the SiC transistor chip 31. Further, the second joint portion 42 includes a solder portion 48.

The solder resist portion 47 divides the region on the anode pad 23 into a first region 51 in which the solder portion 48 and the SiC transistor chip 31 are placed and a second region 52 that is outside the first region 51. One end of a wire 43 is connected to the second region 52.

According to this semiconductor device 11b, when the solder portion 48 included in the second joint portion 42 is melted at the time of joining, the solder resist portion 47 can suppress the solder portion 48 from getting wet and spreading to the second region 52 side. Therefore, this semiconductor device 11b can reduce the influence of the solder portion 48 when connecting the wire 43 to the second region 52 by bonding.

### Embodiment 3

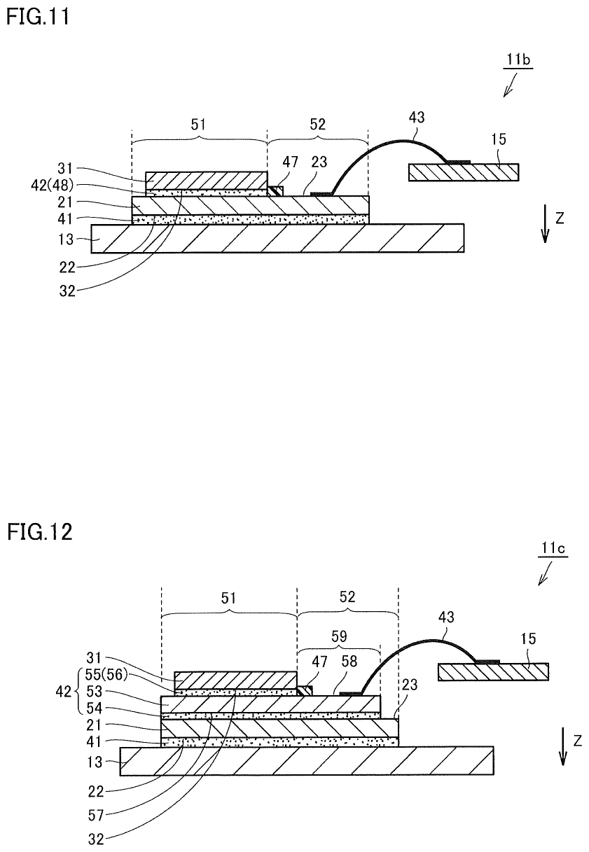

A description will now be made of still yet another embodiment, Embodiment 3. FIG. 12 is a schematic cross-sectional view of a portion of the semiconductor device in Embodiment 3. The semiconductor device of Embodiment 3 differs from that of Embodiment 2 in that the second joint portion includes a first metal plate.

Referring to FIG. 12, a second joint portion 42 included in a semiconductor device 11c according to Embodiment 3 includes a first metal plate 53, a third joint portion 54, and a fourth joint portion 55. The third joint portion 54 contains a sintered bonding material that is a sintered material of fine metal particles. The third joint portion 54 is arranged on the anode pad 23.

The first metal plate 53 is flat. The first metal plate 53 has a thickness that is 30% or more of the thickness of the SiC diode chip 21. In the present embodiment, the first metal plate 53 is thinner than the substrate 13. The first metal plate 53 is arranged on the third joint portion 54. That is, the first metal plate 53 and the anode pad 23 of the SiC diode chip 21 are joined by the third joint portion 54. The first metal plate 53 has a region 59 that does not overlap with the SiC transistor chip 31 as viewed in the thickness direction of the substrate 13.

The fourth joint portion 55 includes a solder portion 56. The fourth joint portion 55 is arranged on the first metal plate 53. Specifically, in a thickness direction of the first metal plate 53, the fourth joint portion 55 is arranged on a surface 58 of the first metal plate 53 opposite to its surface 57 on the side joined to the third joint portion 54. The solder resist portion 47 is arranged on the surface 58. With the solder resist portion 47, a first region 51 in which the fourth joint portion 55 and the SiC transistor chip 31 are arranged is separated from a second region 52 that is outside the first region 51. The SiC transistor chip 31 is arranged on the fourth joint portion 55. That is, the first metal plate 53 and the drain electrode 32 of the SiC transistor chip 31 are joined by the fourth joint portion 55. The region 59 is located in the second region 52. One end of a wire 43 is joined to the surface 58 within the region 59.

According to this semiconductor device 11c, the region of the first metal plate 53 that does not overlap with the SiC transistor chip 31 can be used to secure electrical connection. Further, the first metal plate 53 has high thermal conductivity. Therefore, the heat dissipation of the SiC transistor chip 31 can be ensured by the first metal plate 53 as well. In the above embodiment, the first metal plate 53 is thinner than the substrate 13, enabling downsizing of the semiconductor device 11c. It should be noted that the first metal plate 53 may be about the same thickness as the substrate 13. Here, about the same thickness means a thickness within the range of ±20%. The first metal plate 53 can also be made thicker than the substrate 13. In this case, the heat of the SiC transistor chip 31 spreads across the first metal plate 53, so that the heat is uniformly transferred to the SiC diode chip 21.

FIG. 13 is an enlarged schematic cross-sectional view of a portion of the semiconductor device 11c shown in FIG. 12. Referring to FIG. 13, the heat generated in the SiC transistor chip 31 is transferred to the substrate 13 side via the first metal plate 53 and the SiC diode chip 21. Here, consideration is given to the heat transferred from the transistor chip 31 to the SiC diode chip 21. The rate of thermal diffusion in the thickness direction of the first metal plate 53 and the rate of thermal diffusion in the direction perpendicular to the thickness direction are about the same. Therefore, much of the heat generated in the SiC transistor chip 31 is transferred to the first metal plate 53, with the range that makes an angle of 45 degrees, shown by angle θ₂ in FIG. 4, from the outer edge 36 of the first metal plate 53 relative to the thickness direction as a heat dissipation path. In FIG. 13, an arrow E indicates a part of the heat dissipation path.

Here, a shortest distance W₂ from an outer edge 60 of the first metal plate 53 to the outer edge 36 of the SiC transistor chip 31 is larger than a thickness T₂ of the first metal plate 53. This can suppress the narrowing of the heat dissipation path in the first metal plate 53 from the SiC transistor chip 31 to the substrate 13, allowing the heat generated in the SiC transistor chip 31 to be efficiently transferred to the substrate 13 via the first metal plate 53 and the SiC diode chip 21. Therefore, the above semiconductor device 11c is a semiconductor device capable of efficient heat dissipation.

### Embodiment 4

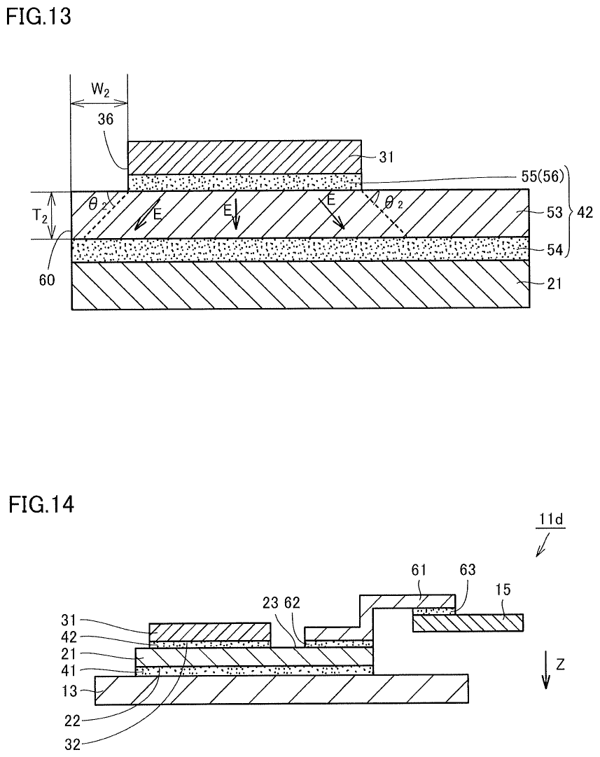

A description will now be made of still yet another embodiment, Embodiment 4. FIG. 14 is a schematic cross-sectional view of a portion of the semiconductor device in Embodiment 4. The semiconductor device of Embodiment 4 differs from that of Embodiment 1 in that it further includes a second metal plate that is joined to a region outside the region in which the SiC transistor chip is arranged.

Referring to FIG. 14, a semiconductor device 11d according to Embodiment 4 includes a second metal plate 61 that is joined to a region outside the region in which the SiC transistor chip 31 is arranged. The second metal plate 61 is formed, for example, by bending a flat metal plate. The second metal plate 61 has a strip shape. The second metal plate 61 has one end connected, by a fifth joint portion 62 made of a conductive material, to a region outside the region in which the SiC transistor chip 31 is arranged, specifically to the anode pad 23 of the SiC diode chip 21. The other end of the second metal plate 61 is joined to the second electrode terminal 15 by a sixth joint portion 63 made of a conductive material.

The second metal plate 61 can easily carry a large current as compared to, for example, a wire 43. With the above configuration, the second metal plate 61 joined to the region outside the region in which the SiC transistor chip 31 is arranged can be used as a bus bar for connecting the SiC diode chip 21 and the second electrode terminal 15, and can be used effectively for electrical connection. It should be noted that the second metal plate 61 may be composed of a plurality of plate-shaped members.

### Embodiment 5

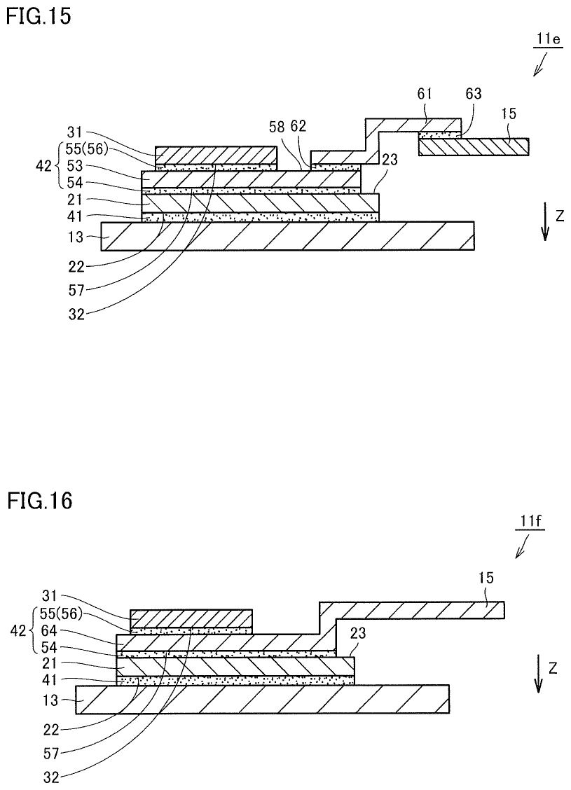

A description will now be made of still yet another embodiment, Embodiment 5. FIG. 15 is a schematic cross-sectional view of a portion of the semiconductor device in Embodiment 5. The semiconductor device of Embodiment 5 differs from that of Embodiment 4 in that the second joint portion includes a first metal plate.

Referring to FIG. 15, a second joint portion 42 included in a semiconductor device 11e according to Embodiment 5 includes a first metal plate 53. The configuration of the second joint portion 42 is similar to that shown in Embodiment 3.

According to this semiconductor device 11e, electrical connection can be secured by using the region of the first metal plate 53 that does not overlap with the SiC transistor chip 31, and by effectively using the second metal plate 61. Further, the first metal plate 53 has high thermal conductivity. Therefore, the heat dissipation of the SiC transistor chip 31 can be ensured by the first metal plate 53 as well.

### Embodiment 6

A description will now be made of still yet another embodiment, Embodiment 6. FIG. 16 is a schematic cross-sectional view of a portion of the semiconductor device in Embodiment 6. The semiconductor device of Embodiment 6 differs from that of Embodiment 5 in that the first metal plate is integrated with the second electrode terminal.

Referring to FIG. 16, a second joint portion 42 included in a semiconductor device 11f according to Embodiment 6 includes a first metal plate 64. The first metal plate 64 is formed, for example, by bending a flat metal plate. The first metal plate 64 has a portion that protrudes from the substrate 13 as viewed in the thickness direction of the substrate 13. The protruding portion constitutes the second electrode terminal 15.

This semiconductor device 11f achieves electrical connection to the second electrode terminal 15 without the intermediary of a bonding material. This can reduce the production process steps. Further, because of the structure involving no bonding material, long-term reliability can also be improved.

### Embodiment 7

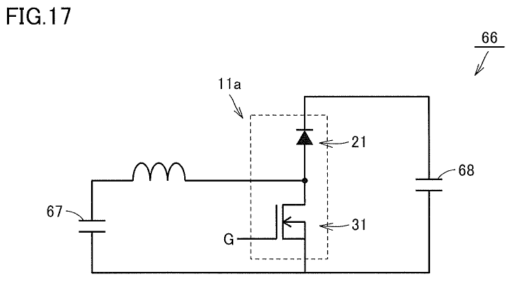

A description will now be made of still yet another embodiment, Embodiment 7. FIG. 17 is a diagram illustrating an equivalent circuit in Embodiment 7. Referring to FIGS. 2 and 17, an equivalent circuit 66 in Embodiment 7 includes the semiconductor device 11a described above, a first capacitor 67, and a second capacitor 68. The first capacitor 67 is arranged between the second electrode terminal 15 and the third electrode terminal 16. The second capacitor 68 is arranged between the first electrode terminal 14 and the third electrode terminal 16. Such an equivalent circuit 66 is used as a module for a booster circuit. The equivalent circuit 66 including the above-described semiconductor device 11a can be used to construct a circuit with twice the step-up ratio by equalizing the load applied to the SiC diode chip 21 and the load applied to the SiC transistor chip 31. The semiconductor devices 11b to 11f described above may, of course, also be used.

### Other Embodiments

In the above embodiments, the transistor chip is a SiC transistor chip 31. However, not limited thereto, the transistor chip may be a transistor chip in which the semiconductor layer is made of Si. Further, the transistor chip may be a transistor chip with another semiconductor layer, in which the semiconductor layer is made of a material with a larger band gap than that of Si, GaN, for example.

In the above embodiments, the substrate having conductivity may be placed on a substrate having insulation. That is, the conductive substrate 13 described above may be arranged on an insulating substrate, and a first bonding material and the like may be arranged thereon. In this manner, for example at the time of production, even when the conductive substrate is thin in thickness, the conductive substrate can be supported by the insulating substrate.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

11a, 11b, 11c, 11d, 11e, 11f: semiconductor device
13: substrate
14: first electrode terminal
15: second electrode terminal
16: third electrode terminal
17: gate terminal
18: Kelvin source terminal
19: encapsulating material
21: SiC diode chip
22: cathode pad
23: anode pad
24, 36, 60; outer edge
31: SiC transistor chip
32: drain electrode
33: source pad
34: gate pad
35: Kelvin source pad
41: first joint portion
42: second joint portion
43, 44, 45, 46: wire
47: solder resist portion
48, 56: solder portion
51: first region
52: second region
53, 64: first metal plate
54: third joint portion
55: fourth joint portion
57, 58: surface
59, 84a, 84b, 84c, 84d, 84e: region
61: second metal plate
62: fifth joint portion
63: sixth joint portion
66: equivalent circuit
67: first capacitor
68: second capacitor
71: corner
72, 73: side
74: intersection
80: copper plate
81: lead frame
82a: first portion
82b: second portion
82c: third portion
82d: fourth portion
83: space
E: path
T₁, T₂: thickness
W₁, W₂: distance
θ₁, θ₂: angle

1. A semiconductor device comprising:
a substrate having conductivity;
a first joint portion having conductivity, arranged on the substrate;
a SiC diode chip arranged on the first joint portion;
a second joint portion having conductivity, arranged on the SiC diode chip; and
a transistor chip arranged on the second joint portion;
the SiC diode chip including a cathode pad arranged on one end in a thickness direction and an anode pad arranged on another end in the thickness direction,
the cathode pad being joined to the substrate by the first joint portion,
the transistor chip including a drain electrode arranged on one end in a thickness direction,
the drain electrode being joined to the anode pad by the second joint portion,
the anode pad being arranged in a region enclosed by an outer edge of the SiC diode chip as viewed in a thickness direction of the substrate,
the anode pad having an area larger than an area of the transistor chip as viewed in the thickness direction of the substrate.

2. The semiconductor device according to claim 1, wherein as viewed in the thickness direction of the substrate, a shortest distance from the outer edge of the SiC diode chip to an outer edge of the transistor chip is larger than a thickness of the SiC diode chip.

3. The semiconductor device according to claim 1, wherein the transistor chip is a SiC transistor chip.

4. The semiconductor device according to claim 3, wherein
a SiC crystal constituting the SiC diode chip has a 4H structure,
a SiC crystal constituting the SiC transistor chip has a 4H structure, and
the SiC crystal constituting the SiC diode chip and the SiC crystal constituting the SiC transistor chip have (0001) planes parallel to each other.

5. The semiconductor device according to claim 4, wherein the SiC crystal constituting the SiC diode chip and the SiC crystal constituting the SiC transistor chip have (11-20) planes parallel to each other.

6. The semiconductor device according to claim 1, wherein the second joint portion contains a sintered bonding material which is a sintered material of fine metal particles.

7. The semiconductor device according to claim 1, wherein
the second joint portion includes a first metal plate that is 30% or more of a thickness of the SiC diode chip, and
the first metal plate has a region that does not overlap with the transistor chip as viewed in the thickness direction of the substrate.

8. The semiconductor device according to claim 1, further comprising a solder resist portion arranged on the anode pad and dividing a region on the anode pad, wherein
the second joint portion includes a solder portion, and
the solder resist portion divides the region on the anode pad, as viewed in the thickness direction of the substrate, into a first region in which the solder portion and the transistor chip are arranged and a second region outside the first region.

9. The semiconductor device according to claim 1, further comprising a second metal plate joined to a region outside a region in which the transistor chip is arranged.

10. The semiconductor device according to claim 2, wherein the transistor chip is a SiC transistor chip.

11. The semiconductor device according to claim 2, wherein the second joint portion contains a sintered bonding material which is a sintered material of fine metal particles.

12. The semiconductor device according to claim 3, wherein the second joint portion contains a sintered bonding material which is a sintered material of fine metal particles.

13. The semiconductor device according to claim 4, wherein the second joint portion contains a sintered bonding material which is a sintered material of fine metal particles.

14. The semiconductor device according to claim 5, wherein the second joint portion contains a sintered bonding material which is a sintered material of fine metal particles.

15. The semiconductor device according to claim 2, wherein
the second joint portion includes a first metal plate that is 30% or more of a thickness of the SiC diode chip, and
the first metal plate has a region that does not overlap with the transistor chip as viewed in the thickness direction of the substrate.

16. The semiconductor device according to claim 3, wherein
the second joint portion includes a first metal plate that is 30% or more of a thickness of the SiC diode chip, and
the first metal plate has a region that does not overlap with the transistor chip as viewed in the thickness direction of the substrate.

17. The semiconductor device according to claim 4, wherein
the second joint portion includes a first metal plate that is 30% or more of a thickness of the SiC diode chip, and
the first metal plate has a region that does not overlap with the transistor chip as viewed in the thickness direction of the substrate.

18. The semiconductor device according to claim 5, wherein
the second joint portion includes a first metal plate that is 30% or more of a thickness of the SiC diode chip, and
the first metal plate has a region that does not overlap with the transistor chip as viewed in the thickness direction of the substrate.

19. The semiconductor device according to claim 6, wherein
the second joint portion includes a first metal plate that is 30% or more of a thickness of the SiC diode chip, and
the first metal plate has a region that does not overlap with the transistor chip as viewed in the thickness direction of the substrate.

20. The semiconductor device according to claim 2, further comprising a solder resist portion arranged on the anode pad and dividing a region on the anode pad, wherein
the second joint portion includes a solder portion, and
the solder resist portion divides the region on the anode pad, as viewed in the thickness direction of the substrate, into a first region in which the solder portion and the transistor chip are arranged and a second region outside the first region.
